(19) United States
(12) Patent Application Publication
(10) Pub. No.: US 2012/0212908 A1
(43) Pub. Date: Aug. 23, 2012

(54) FLAT DISPLAY DEVICE

(76) Inventors: Suguru Nakao, Hyogo (JP); Shouichi Irie, Osaka (JP)

(21) Appl. No.: 13/397,254

(22) Filed: Feb. 15, 2012

(30) Foreign Application Priority Data
Feb. 21, 2011 (JP) 2011-034085

(51) Int. Cl. H05K 5/02

(52) U.S. Cl. 361/724

(57) ABSTRACT

Provided is a flat display device comprising an outer cabinet in a frame shape, wherein at least one side of a frame section of the outer cabinet includes a decorative bar, which is formed by sequentially laminating a second member transmitting light and a third member having a smaller refractive index than that of the second member on a first member having a reflecting surface to reflect light, and is provided with a light-emitting unit, which emits light, in a portion opposed to an end surface of the second member of the decorative bar.

### BACKGROUND OF THE INVENTION

1. Field of the Invention

The present invention relates to a flat display device using a plasma display panel, a liquid crystal display panel or the like as a display device, and more specifically relates to a technique for forming an outer cabinet of the flat display device at low cost without deterioration in design.

2. Description of the Related Art

In recent years, there have been widespread flat display devices each using a plasma display panel, a liquid crystal panel or the like as a display device. Among them, the plasma display panel is broadly divided into an AC drive type and a DC drive type, and also into two kinds of discharge forms, a surface discharge type and a counter discharge type. Under present circumstances, a surface discharge type plasma display panel with a three-electrode structure has been mainstream from viewpoints of high definition, large screen and simplicity of manufacturing.

In the surface discharge type plasma display panel, a pair of substrates, each being transparent at least on a front surface side thereof, is disposed as opposed to each other such that a discharge space is formed between those substrates, and barrier ribs for partitioning the discharge space into a plurality of spaces are disposed inside the substrate. Further, in the plasma display panel, an electrode group is disposed on the substrate so as to generate discharge with respect to each discharge space partitioned by barrier ribs, and respective phosphors which emit red, green and blue light by discharge are provided with respect to each discharge space, to regularly dispose respective discharge cells for red, green and blue. Then, in the plasma display panel, during operation, the respective phosphors are excited by vacuum ultraviolet light with a short wavelength generated by discharge, and red, green and blue visible light are emitted respectively from arbitrary discharge cells for red, green and blue, to perform a color display.

A plasma display device using such a plasma display panel is particularly drawing attention in recent years since being capable of performing a fast display, having a wide angle of visibility, and being easy to increase in size as compared with a liquid crystal display device using the liquid crystal panel, as well as being a self-luminous type so as to have high display quality. Further, the plasma display device is in use for a variety of applications mainly as a large-screen display device in a place where a large number of people get together or as a main display device to entertain every family member at home.

Concerning the plasma display device, Japanese Unexamined Patent Publication No. 2005-331556 discloses an example where a panel mainly composed of glass is held on a front surface side of a chassis member made of metal such as aluminum, and a circuit board constituting a drive circuit for light emission of the panel is disposed on a rear surface side of the chassis member.

Meanwhile, concerning a conventional flat display device, Japanese Unexamined Patent Publication No. 2009-267575 discloses an outer cabinet of an assembly type which is divided into four pieces, and then brought together on the rear surface side. This outer cabinet has been devised in order to reduce manufacturing cost of an injection-molding mold. Although this outer cabinet is not a two-color injection molded article, two-color molten resins are injected into respective divided molds, whereby a gradation effect can be obtained.

However, in the flat display device, an outer cabinet with further improved design has been required.

### SUMMARY OF THE INVENTION

A flat display device of the present invention is a flat display device comprising an outer cabinet in a frame shape, and at least one side of one of the frame sections of the outer cabinet includes a decorative bar which is formed by sequentially laminating a second member transmitting light and a third member having a smaller refractive index than that of the second member on a first member having a reflecting surface to reflect light. Then, a light-emitting unit, which emits light in a portion opposed to an end surface of the second member of the decorative bar, is provided.

Further, a flat display device of the present invention is a flat display device comprising an outer cabinet in a frame shape, wherein the outer cabinet is configured of frame sections formed by extrusion, and corner sections that connect the frame sections together. Moreover, at least one side of one of the frame sections includes a decorative bar which is formed by sequentially laminating a second member transmitting light and a third member having a smaller refractive index than that of the second member on a first member having a reflecting surface to reflect light. Then, a light-emitting unit, which emits light in the corner sections opposed to an end surface of the second member of the decorative bar, may be disposed.

With such a configuration, the frame section of at least one side of the outer cabinet has the decorative bar, which is formed by sequentially laminating the second member transmitting light and the third member having a smaller refractive index than that of the second member on the first member having the reflecting surface to reflect light, and is provided with the light-emitting unit which emits light in the portion opposed to the end surface of the second member of the decorative bar. Hence, it is possible to make a light line displayed on the decorative bar for example when a power supply of the flat display device is switched on, so as to obtain a product excellent in design as well as enhancing visibility of an operating state of the flat display device.

Furthermore, due to provision of the decorative bar formed by sequentially laminating the second member transmitting light and the third member having a smaller refractive index than that of the second member on the first member having the reflecting surface to reflect light, light emitted from the light-emitting unit is transmitted through the third member, while being repeatedly reflected between the reflecting surface of the first member and the third member, and output from the front surface. This can increase a traveling length of light.

### BRIEF DESCRIPTION OF THE DRAWINGS

FIG. 1 is a front view showing an external view of a liquid crystal display device according to an exemplary embodiment of the present invention.

FIG. 2 is a perspective view showing a state where a stand has been removed in the liquid crystal display device according to the exemplary embodiment of the present invention.

FIG. 3 is a block diagram showing a circuit block of an entire configuration of the liquid crystal display device according to the exemplary embodiment of the present invention.

FIG. 4 is a plan view shown with a back cabinet removed for explaining an example of disposition of the circuit block of the liquid crystal display device according to the exemplary embodiment of the present invention.

FIG. 5 is a plan view showing a schematic configuration of a front cabinet of the liquid crystal display device according to the exemplary embodiment of the present invention.

FIG. 6 is a perspective view showing a frame section of lower one side of the front cabinet of the liquid crystal display device according to the exemplary embodiment of the present invention.

FIG. 7 is a sectional view taken along a cross section 7-7 of FIG. 5.

FIG. 8 is an explanatory view for explaining a function in a decorative bar of the liquid crystal display device according to the exemplary embodiment of the present invention.

FIG. 9 is a perspective view showing another example of the decorative bar according to another exemplary embodiment of the present invention.

FIG. 10 is a perspective view showing another example of the decorative bar according to the exemplary embodiment of the present invention.

FIG. 11 is a plan view showing another example of the decorative bar according to the exemplary embodiment of the present invention.

FIG. 12 is an exploded perspective view showing another example of the front cabinet according to the exemplary embodiment of the present invention.

### DETAILED DESCRIPTION OF PREFERRED EMBODIMENT

### Exemplary Embodiment

Hereinafter, a flat display device according to an exemplary embodiment of the present invention will be described with reference to the drawings by taking a liquid crystal display device as an example.

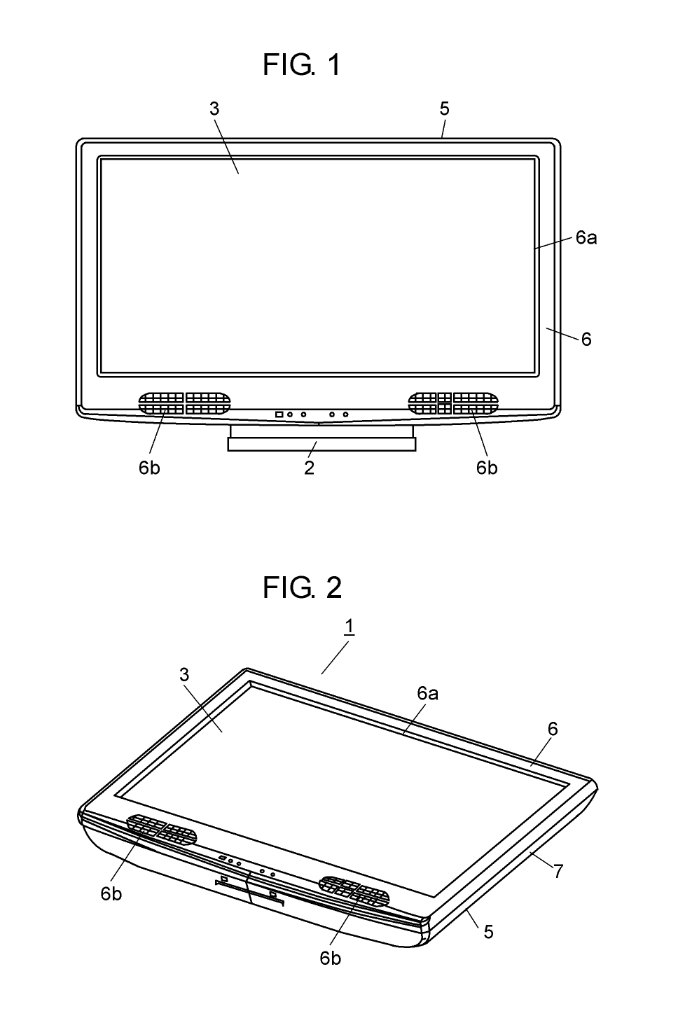

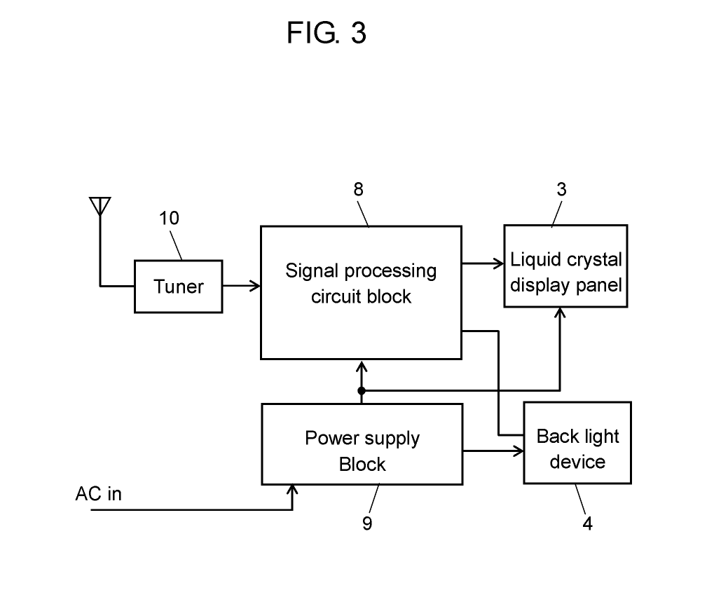

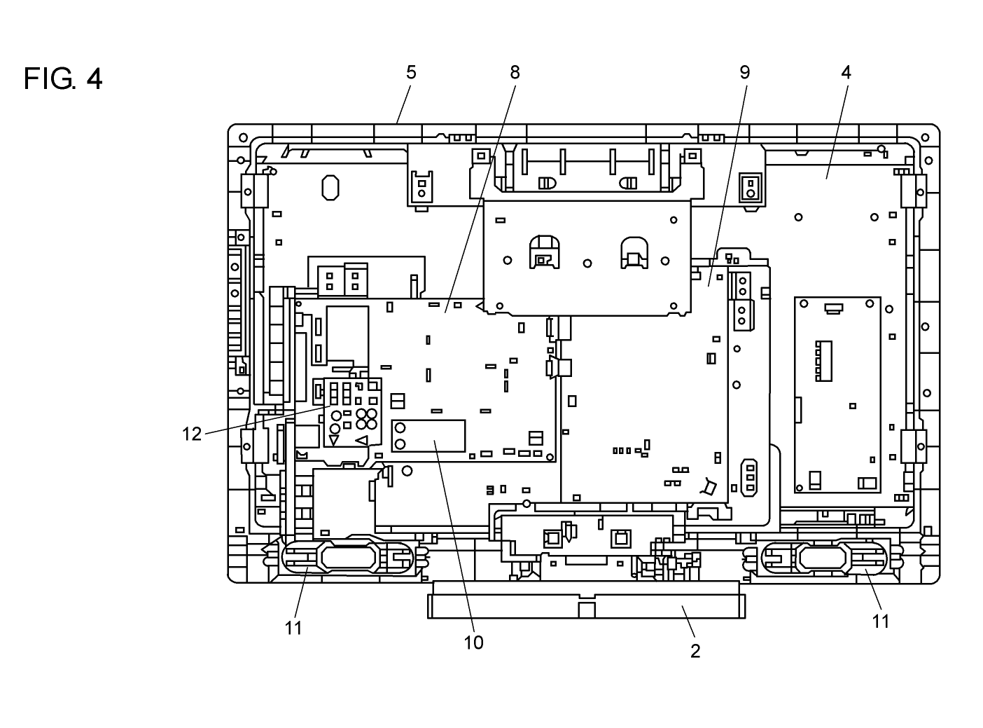

FIG. 1 is a front view showing an external view of a liquid crystal display device according to an exemplary embodiment of the present invention. FIG. 2 is a perspective view showing a state where stand 2 has been removed in the liquid crystal display device according to the exemplary embodiment of the present invention. FIG. 3 is a diagram showing a circuit block of an entire configuration of the liquid crystal display device according to the exemplary embodiment of the present invention. FIG. 4 is a view shown with back cabinet 7 removed for explaining an example of disposition of the circuit block of the liquid crystal display device according to the exemplary embodiment of the present invention.

First, as shown in FIGS. 1 and 2, a liquid crystal display device as a flat display device has display device body 1 and stand 2 that holds display device body 1 in an erected state. A display module configured of liquid crystal display panel 3 as a flat type display panel and back light device 4 is housed into outer cabinet 5 made up of a resin molded article or the like, to constitute display device body 1. Further, outer cabinet 5 is configured of front cabinet 6 and back cabinet 7. Front cabinet 6 in a frame shape is provided with opening 6a so as to correspond to an image displayed area of liquid crystal display panel 3. Then, back cabinet 7 is disposed in combination with front cabinet 6. It is to be noted that speaker grille 6b is disposed on a front surface side of front cabinet 6 for effectively emitting a sound of a speaker to the forward outside of display device body 1.

Next, a schematic configuration of the entire liquid crystal display device will be described with reference to FIGS. 3 and 4. The liquid crystal display device is provided with a drive circuit that displays an image on liquid crystal display panel 3, while being configured of signal processing circuit block 8 including a light control circuit for controlling lightening of back light device 4, liquid crystal display panel 3, back light device 4, power supply block 9 for supplying a power supply voltage to signal processing circuit block 8, tuner 10 that receives television broadcasting and supplies a reception signal to signal processing circuit block 8, and speaker 11 for outputting a sound. Signal processing circuit block 8 and power supply block 9 are each configured by mounting components that constitute a circuit on a circuit board. The circuit board mounted with signal processing circuit block 8, power supply block 9, tuner 10 and the like is fitted so as to be disposed in a space between a rear surface of back light device 4 and back cabinet 7.

It is to be noted that the speaker is omitted in FIG. 3. Further, as shown in FIG. 4, outside signal inputting terminal 12 for inputting a video signal from an external device such as a DVD player into the liquid crystal display device is mounted in signal processing circuit block 8.

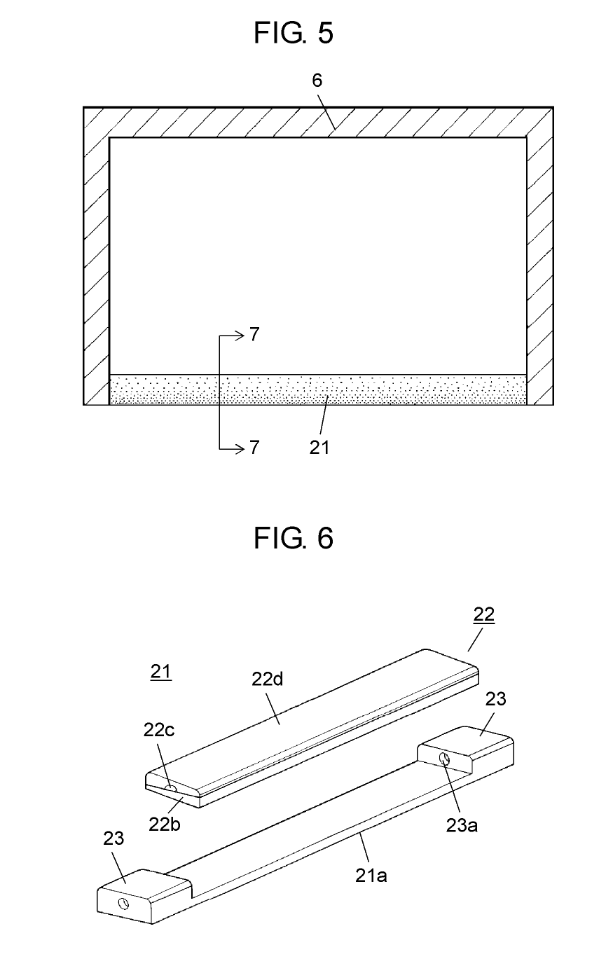

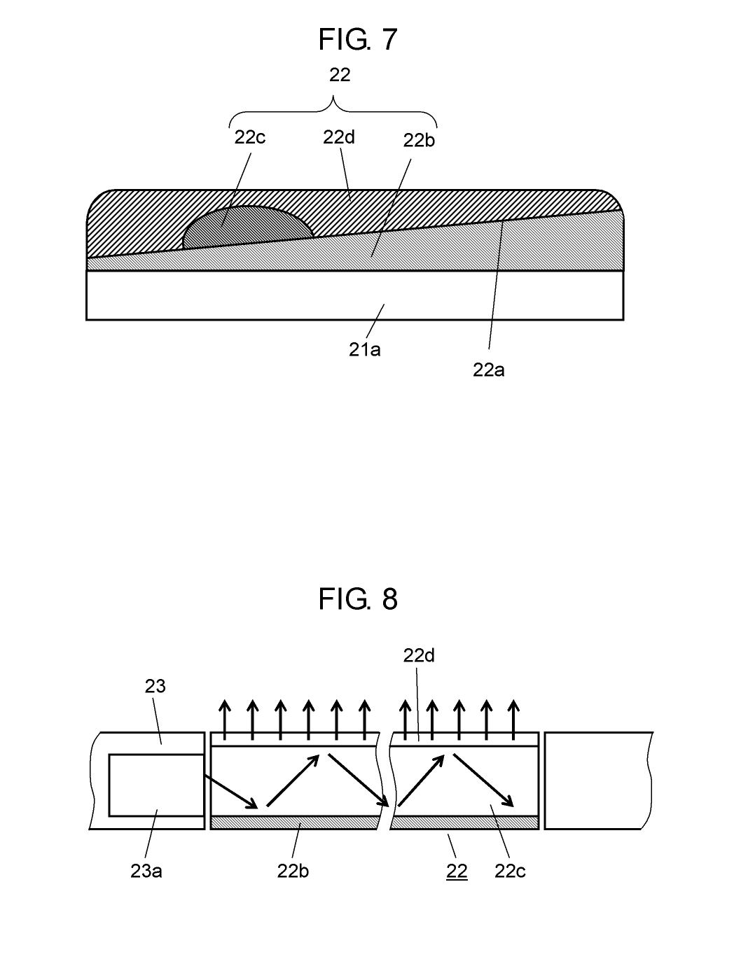

FIG. 5 is a plan view showing a schematic configuration of front cabinet 6 of the liquid crystal display device according to the exemplary embodiment of the present invention. FIG. 6 is a perspective view showing frame section 21 of lower one side of front cabinet 6. FIG. 7 is a sectional view taken along a cross section 7-7 of FIG. 5.

As shown in FIGS. 5 to 7, frame section 21 of lower one side of front cabinet 6 is configured such that decorative bar 22 is fitted to frame section substrate 21a, and light-emitting unit 23 provided with light-emitting diode 23a that emits light is disposed in each end section of frame section substrate 21a. Further, decorative bar 22 is configured by sequentially laminating second member 22c made of a transparent resin transmitting light and third member 22d made of a colored transparent resin having a smaller refractive index than that of second member 22c on first member 22b having reflecting surface 22a to reflect light. Moreover, a light-emitting surface of light-emitting diode 23a of light-emitting unit 23 is provided in a portion opposed to the end surface of second member 22c of decorative bar 22. Herein, entire first member 22b of decorative bar 22 is made up of metal such as aluminum. Alternatively, first member 22b may be made of a resin and particles of metal such as aluminum may be applied to reflecting surface 22a so that at least reflecting surface 22a may be made up of metal.

Moreover, in decorative bar 22, second member 22c and third member 22d can be formed by extrusion with use of two kinds of resins.

FIG. 8 is a view for explaining a function in decorative bar 22 of the liquid crystal display device according to the exemplary embodiment of the present invention. As shown in FIG. 8, lower frame section 21 of front cabinet 6 is provided with decorative bar 22 and light-emitting unit 23. Further, decorative bar 22 is configured by sequentially laminating second member 22c transmitting light and third member 22d having a smaller refractive index than that of second member 22c on first member 22b having reflecting surface 22a to reflect light. For this reason, light emitted from light-emitting diode 23a of light-emitting unit 23 is reflected on reflecting surface 22a of first member 22b, and output from a front surface of third member 22d. At this time, since third member 22d has a small refractive index as compared with that of second member 22c, light having reached third member 22d travels toward the front surface of third member 22d while a part thereof is reflected and travels toward an inside of second member 22c. Then, light having returned to the side of second member 22c is again reflected on reflecting surface 22a of first member 22b, and travels toward third member 22d, and the emission and reflection of light are repeated. While such emission and reflection of light are repeated, light travels inside decorative bar 22, leading to an increase in travelling length of light of light-emitting diode 23a. It is therefore possible to make light of light-emitting diode 23a reach entire decorative bar 22, and also to emit light from entire decorative bar 22, so as to enhance visibility of decorative bar 22.

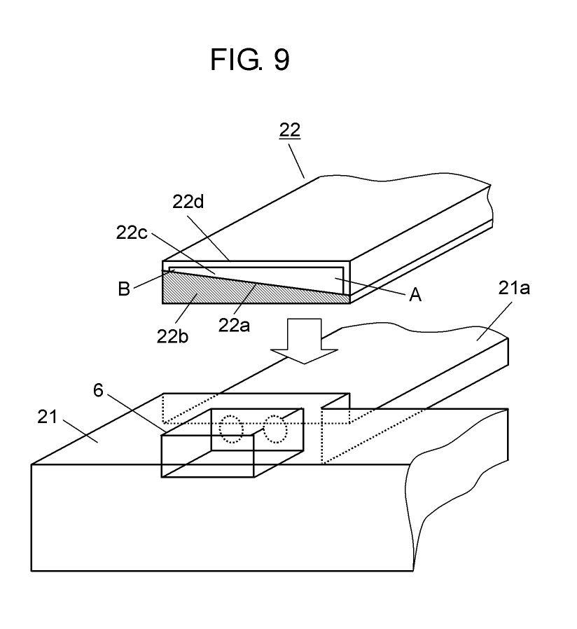

Next, another example of the decorative bar in the present exemplary embodiment will be described. FIG. 9 is a perspective view showing another example of decorative bar 22 in an exemplary embodiment of the present invention. Herein, as shown in FIG. 9, in decorative bar 22, second member 22c and third member 22d are formed by extrusion in decorative bar 22, and the extruded articles and first member 22b having reflecting surface 22a are shaped with thicknesses successively varying in a width direction of decorative bar 22. Further, as shown in FIG. 9, second member 22c has a cross-section shape with almost the same degree of width as that of first member 22b.

As thus described, the extruded article and first member 22b having reflecting surface 22a are shaped with thicknesses successively varying in the width direction of decorative bar 22, and it is thereby possible to make an expression by a gradation effect when decorative bar 22 is seen from the front surface side of third member 22d.

For example, in portion A where a thickness of second member 22c made of a transparent resin is larger than that of first member 22b having reflecting surface 22a, with reflecting surface 22a located in a deep position, an amount of reflected light is small and it is thus dark. On the contrary, in portion B where the thickness of second member 22c is smaller than that of first member 22b, with reflecting surface 22a located in a shallow position, the amount of reflected light is large and it is thus bright. Further, when the resin of second member 22c is a colored transparent resin, an expression by means of the gradation effect is made more clearly. Moreover, for exerting the gradation effect even when decorative bar 22 is seen from a diagonal direction, a side surface of decorative bar 22 may also be made to have a varied thickness similarly to the above.

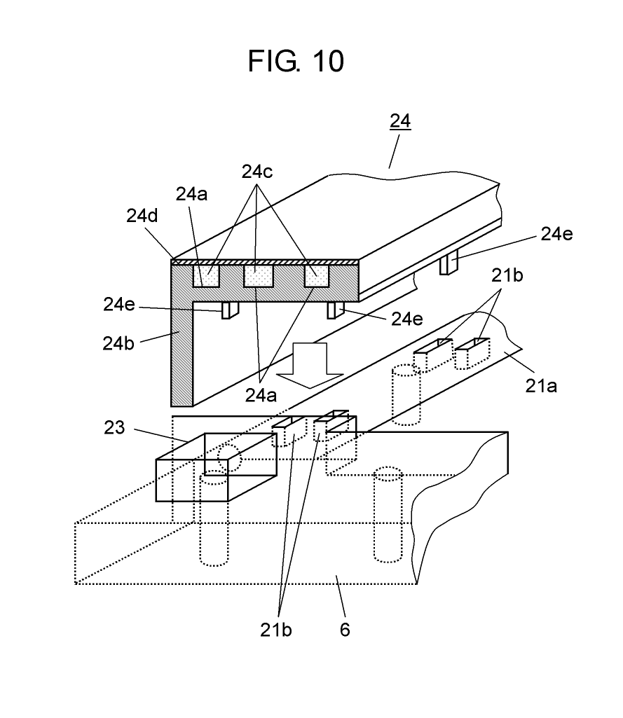

FIG. 10 is a perspective view showing another example of decorative bar 24 in the exemplary embodiment of the present invention. In the example shown in FIG. 10, L-shaped decorative bar 24 is used. Decorative bar 24 has L-shaped metal-made first member 24b having concave-convex reflecting surface 24a, and is configured by sequentially laminating second member 24c made of a transparent resin transmitting light and third member 24d in a flat shape having a smaller refractive index than that of second member 24c on concave-convex reflecting surface 24a of first member 24b. Further, a plurality of protrusions 24e is provided on a surface to be fitted to frame section 21 in first member 24b of decorative bar 24, while holes 21b where protrusions 24e are to be inserted are provided in frame section substrate 21a of frame section 21.

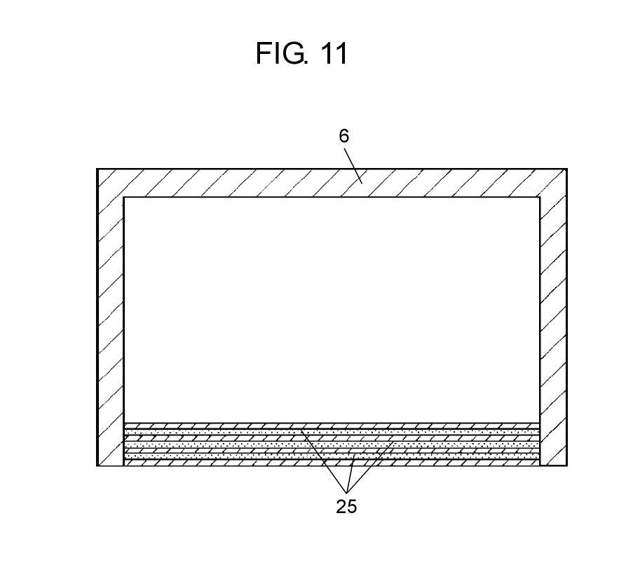

With use of decorative bar 24 shown in FIG. 10, a plurality of light lines 25 can be expressed in a lower section of front cabinet 6 by means of concave-convex reflecting surface 24a of first member 24b, as shown in FIG. 11, so as to improve design.

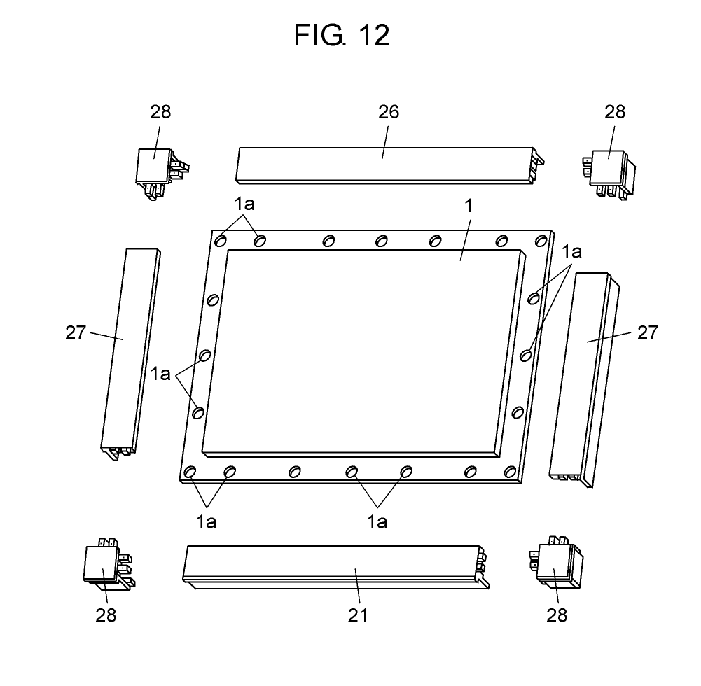

FIG. 12 is an exploded perspective view showing another example of front cabinet 6 in an exemplary embodiment of the present invention.

In the example shown in FIG. 12, display device body 1 is provided with fitting holes 1a used for fixing front cabinet 6 by means of screws. Front cabinet 6 is configured of frame sections 26, 27 formed by extrusion and corner sections 28 that connect frame sections 26, 27 together. For frame section 26 of lower one side among frame sections 26, 27, frame section 21 shown in FIGS. 5 to 7 is used.

That is, lower frame section 21 has decorative bar 22, which is formed by sequentially laminating second member 22c transmitting light and third member 22d having a smaller refractive index than that of second member 22c on first member 22b having reflecting surface 22a to reflect light, and is provided with light-emitting unit 23 (not shown in FIG. 12) which emits light in corner section 28 opposed to the end surface of second member 22c of decorative bar 22.

As thus described, in the present invention, frame section 21 of at least one of front cabinet 6 constituting outer cabinet 5 has decorative bar 22, which is formed by sequentially laminating second member 22c transmitting light and third member 22d having a smaller refractive index than that of second member 22c on first member 22b having reflecting surface 22a to reflect light, and is provided with light-emitting unit 23 which emits light, in portions opposed to the end surface of second member 22c of decorative bar 22.

Hence, it is possible to make a light line displayed on the decorative bar for example when a power supply of the flat display device is switched on, so as to obtain a product excellent in design as well as enhancing visibility of an operating state of the flat display device. Furthermore, due to provision of decorative bar 22 formed by sequentially laminating second member 22c transmitting light and third member 22d having a smaller refractive index than that of second member 22c on first member 22b having reflecting surface 22a to reflect light, light emitted from light-emitting unit 23 is transmitted through third member 22d, while being repeatedly reflected between reflecting surface 22a of first member 22b and third member 22d, and output from the front surface. This can increase a traveling length of light and can further enhance visibility.

What is claimed is:

1. A flat display device comprising an outer cabinet in a frame shape, wherein
at least one side of one of the frame sections of the outer cabinet includes a decorative bar, which is formed by sequentially laminating a second member transmitting light and a third member having a smaller refractive index than that of the second member on a first member having a reflecting surface to reflect light, and is provided with a light-emitting unit, which emits light, in a portion opposed to an end surface of the second member of the decorative bar.

2. The flat display device according to claim 1, wherein the second member and the third member are formed by extrusion in the decorative bar of the outer cabinet.

3. The flat display device according to claim 1, wherein the reflecting surface of the first member is formed of metal in the decorative bar of the outer cabinet.

4. The flat display device according to claim 1, wherein
the second member and the third member are formed by extrusion in the decorative bar of the outer cabinet, and
the extruded articles and the first member having the reflecting surface are shaped with thicknesses successively varying in a width direction of the decorative bar.

5. A flat display device comprising an outer cabinet in a frame shape, wherein
the outer cabinet is configured of frame sections formed by extrusion, and corner sections that connect the frame sections together, and
at least one side of one of the frame sections includes a decorative bar, which is formed by sequentially laminating a second member transmitting light and a third member having a smaller refractive index than that of the second member on a first member having a reflecting surface to reflect light, and is provided with a light-emitting unit, which emits light, in the corner sections opposed to an end surface of the second member of the decorative bar.

6. The flat display device according to claim 5, wherein the second member and the third member are formed by extrusion in the decorative bar of the outer cabinet.

7. The flat display device according to claim 5, wherein the reflecting surface of the first member is formed of metal in the decorative bar of the outer cabinet.

8. The flat display device according to claim 5, wherein
the second member and the third member are formed by extrusion in the decorative bar of the outer cabinet, and
the extruded article and the first member having the reflecting surface are shaped with thicknesses successively varying in a width direction of the decorative bar.
